(19) United States
(12) Patent Application Publication
(10) Pub. No.: US 2021/0280703 A1
(43) Pub. Date: Sep. 9, 2021

(54) CHARGE-TRAPPING LAYERS FOR III-V SEMICONDUCTOR DEVICES

(71) Applicant: GLOBALFOUNDRIES U.S. Inc., Santa Clara, CA (US)

(72) Inventors: Bartlomiej J. Pawlak, Leuven (BE); Dimitri Lederer, Court-Saint-Etienne (BE)

(21) Appl. No.: 16/807,623

(22) Filed: Mar. 3, 2020

(51) Int. Cl. H01L 29/778; H01L 29/15; H01L 29/16; H01L 29/20; H01L 29/205; H01L 29/66; H01L 21/02

(52) U.S. Cl. CPC H01L 29/7785; H01L 29/157; H01L 29/16; H01L 29/2003; H01L 29/205; H01L 21/02507; H01L 21/0262; H01L 21/0254; H01L 21/0245; H01L 21/02458; H01L 29/66462

(57) ABSTRACT

Structures including a buffer layer and methods of forming a structure including a buffer layer. A layer stack is formed on a semiconductor substrate. The layer stack includes a buffer layer and a charge-trapping layer. The buffer layer is composed of a III-V compound semiconductor material, and the charge-trapping layer is positioned between the semiconductor substrate and the buffer layer.

### BACKGROUND

The invention relates generally to semiconductor device fabrication and integrated circuits and, in particular, to structures including a buffer layer and methods of forming a structure including a buffer layer.

High-speed and high-frequency electronic devices may be fabricated using III-V compound semiconductors to exploit material properties, such as a higher carrier mobility than silicon. These electronic devices may be formed using a layer stack that includes III-V compound semiconductors grown on a silicon substrate. The layer stack includes a channel layer that is used to fabricate the electronic device. Most crystalline III-V compound semiconductors are lattice mismatched with single-crystal silicon. Consequently, a buffer layer is typically positioned between the silicon substrate and the channel layer to accommodate the lattice mismatch. The buffer layer provides a smooth adaptation of the mismatch in lattice constant between silicon and the III-V compound semiconductor material of the channel layer during epitaxial growth. The buffer layer may permit the channel layer to be epitaxially grown possibly defect free. The buffer layer may also provide either a relaxed or strained channel layer tailored to optimize carrier mobility for high on-state currents.

The buffer layer may be formed on a high-resistivity silicon substrate. During device operation, direct carrier spill from the buffer layer may create a conductive layer of charge carriers (e.g., a sea of electrons) in the silicon substrate beneath the buffer layer. Charge carriers may be also attracted by electrostatic forces from the substrate toward the buffer layer and contribute to forming the conductive layer. The charge carriers contained in the conductive layer may unwantedly reduce the electrical resistivity of the silicon substrate and may also contribute to radio-frequency losses and non-linear effects.

Improved structures including a buffer layer and methods of forming a structure including a buffer layer are needed.

### SUMMARY

In an embodiment of the invention, a structure includes a semiconductor substrate and a layer stack on the semiconductor substrate. The layer stack includes a buffer layer and a charge-trapping layer. The buffer layer is composed of a III-V compound semiconductor material, and the charge-trapping layer is positioned between the semiconductor substrate and the buffer layer.

In an embodiment of the invention, a method includes forming a charge-trapping layer on a semiconductor substrate and forming a buffer layer on the charge-trapping layer. The buffer layer is comprised of a III-V compound semiconductor material, and the charge-trapping layer is positioned between the semiconductor substrate and the buffer layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is cross-sectional view of a structure for a layer stack in accordance with embodiments of the invention.

FIG. 2 is a cross-sectional view of the structure at a fabrication stage subsequent to FIG. 1.

FIG. 3 is cross-sectional view of a structure for a layer stack in accordance with alternative embodiments of the invention.

FIG. 4 is cross-sectional view of a structure for a layer stack in accordance with alternative embodiments of the invention.

### DETAILED DESCRIPTION

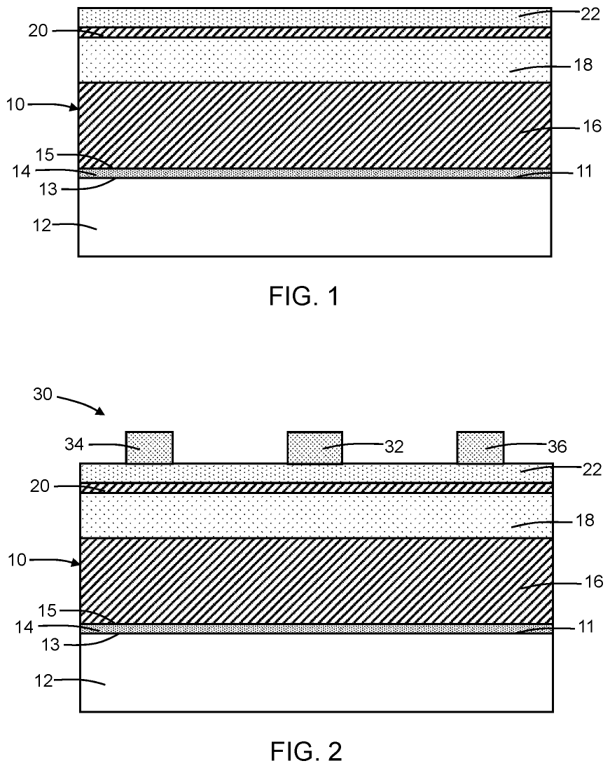

With reference to FIG. 1 and in accordance with embodiments of the invention, a layer stack 10 is formed on a top surface 11 of a semiconductor substrate 12. The semiconductor substrate 12 may be composed of a single-crystal semiconductor material, such as single-crystal silicon. The semiconductor substrate 12 may be a bulk substrate composed of single-crystal semiconductor material (e.g., single-crystal silicon), and the bulk substrate may be a high-resistivity bulk wafer. Generally, a high-resistivity bulk substrate may contain silicon having an electrical resistivity greater than or equal to 100 ohm-cm. In an embodiment, the high-resistivity bulk substrate may have an electrical resistivity that is greater than or equal to 1000 ohm-cm.

The layer stack 10 may include a charge-trapping layer 14, a buffer layer 16, a channel layer 18, a spacer layer 20, and a barrier layer 22. The layers 14, 16, 18, 20, 22 may be serially formed using an epitaxial growth process, such as metalorganic chemical vapor deposition, and the layers 14, 16, 18, 20, 22 may each include single-crystal material. The buffer layer 16 may have multiple sub-layers that are tailored in terms of material and layer thickness to accommodate the lattice mismatch between the material of the semiconductor substrate 12 and the material of the channel layer 18. The buffer layer 16 may include a seed layer composed of a material, such as aluminum nitride, adjacent to the semiconductor substrate 12. The channel layer 18, which is disposed over the buffer layer 16, may be composed of a III-V compound semiconductor material, such as gallium nitride. The spacer layer 20 and the barrier layer 22 are disposed over the channel layer 18 with the spacer layer 20 between the channel layer 18 and the barrier layer 22. The spacer layer 20 may be thin and composed of a material such as aluminum nitride. The barrier layer 22 may be composed of a material, such as indium aluminum nitride, that provides a strained interface with the channel layer 18. The barrier layer 22 provides a contribution, along with the material properties of the channel layer 18, to create a two-dimensional electron gas, during device operation, that is filled with highly-mobile and abundant electrons.

The charge-trapping layer 14 is located in a vertical direction between the buffer layer 16 of the layer stack 10 and the semiconductor substrate 12. The charge-trapping layer 14 has a lower surface 13 located over the semiconductor substrate 12 and an upper surface 15 opposite to the lower surface 13. The lower surface 13 of the charge-trapping layer 14 is positioned on, and defines an interface that may be in direct contact with, the top surface 11 of the semiconductor substrate 11. The upper surface 15 of the charge-trapping layer 14 is positioned beneath, and defines an interface that may be in direct contact with, a lower surface of the buffer layer 16.

The charge-trapping layer 14 may be composed of a semiconductor material containing an atomic concentration of an element that provides charge traps. In an embodiment, the charge-trapping layer 14 may be composed of a single-crystal semiconductor material and may contain an atomic concentration of a homologous element (i.e., an element appearing in the same Group (column) of the Periodic Table). In an embodiment, the charge-trapping layer 14 may be composed of single-crystal silicon and may contain an atomic concentration of an element (e.g., carbon) from Group IV of the Periodic Table. In an embodiment, the charge-trapping layer 14 may be composed of single-crystal silicon and may contain an atomic concentration of an element, such as carbon, that is non-doping in single-crystal silicon to provide the charge traps. A non-doping element has a negligible effect on the electrical conductivity of the single-crystal silicon. In an embodiment, the charge-trapping layer 14 may be composed of single-crystal silicon and may contain an atomic concentration of carbon that provides the charge traps. In an embodiment, the atomic concentration of carbon in the single-crystal silicon may be within a range of about one tenth (0.1) atomic percent to about three (3) atomic percent. Without being limited by theory, the carbon atoms are believed to occupy interstitial sites within the diamond crystal lattice structure of single-crystal silicon and to form carbon-silicon complexes that act as electrically-active carrier traps. In an embodiment, the charge-trapping layer 14 may have a thickness within a range of one (1) nanometer (nm) to one (1) micron (μm).

With reference to FIG. 2 in which like reference numerals refer to like features in FIG. 1 and at a subsequent fabrication stage of the processing method, a device structure 30 is formed using the layer stack 10. In an embodiment, the device structure 30 may be a high-electron-mobility transistor (HEMT) that includes a gate electrode 32, a source 34, and a drain 36 that are each located over the channel layer 18. While not shown, the layer stack 10 may be patterned with lithography and etching processes in association with the formation of the device structure 30 to define a raised mesa that is encapsulated by subsequently-deposited dielectric material. The device structure 30 formed using the layer stack 10 may also be a different type of active or passive device other than a high-electron-mobility transistor.

The charge-trapping layer 14 may provide a region that includes electrical defects that are capable of trapping free charge carriers. The charge-trapping layer 14 may alleviate or mitigate the conductive layer of charge carriers (e.g., the sea of electrons) that is induced, during operation of the device structure 30, in the semiconductor substrate 12 directly beneath the buffer layer 16. The trapping of the charge carriers preserves the electrical resistivity of the semiconductor substrate 12. The charge-trapping layer 14 may eliminate or significantly alleviate the impact from the conductive layer of charge carriers upon high-frequency device operation.

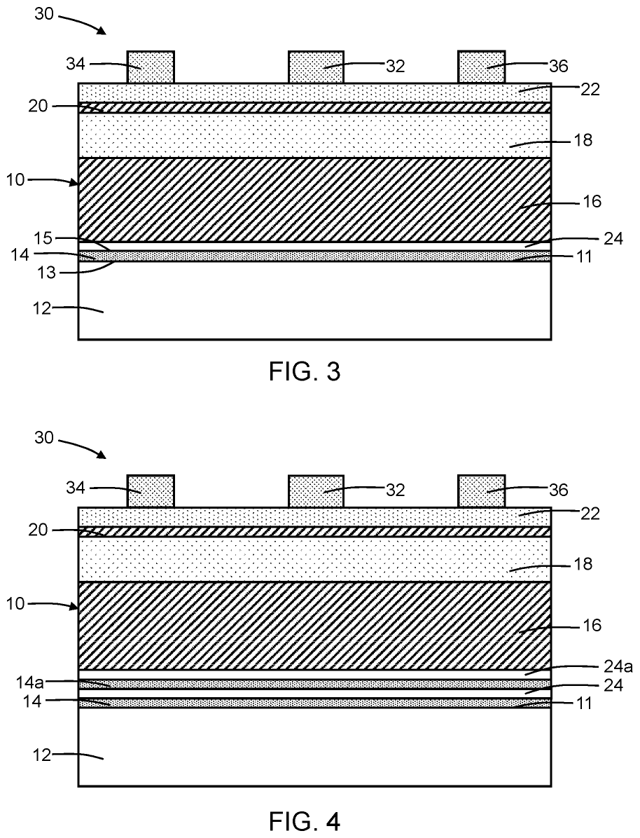

With reference to FIG. 3 in which like reference numerals refer to like features in FIG. 2 and in accordance with alternative embodiments of the invention, a cap layer 24 may be positioned over the charge-trapping layer 14 and located in a vertical direction between the buffer layer 16 of the layer stack 10 and the charge-trapping layer 14. In an embodiment, the cap layer 24 may be composed of the same single-crystal semiconductor material (e.g., single-crystal silicon) as the charge-trapping layer 14, with the exception of lacking the concentration of atoms that provide the charge traps, such that the cap layer 24 is free of these atoms. The upper surface 15 of the charge-trapping layer 14 is positioned beneath and defines an interface that may be in direct contact with a lower surface of the cap layer 24.

With reference to FIG. 4 in which like reference numerals refer to like features in FIG. 2 and in accordance with alternative embodiments of the invention, the charge-trapping layer 14 and the cap layer 24 may be replicated in pairs to define a stacked superlattice structure. In the representative embodiment, an additional charge-trapping layer 14a similar or identical to the charge-trapping layer 14 and an additional cap layer 24a may be formed over the layers 14, 24.

In an embodiment, the charge-trapping layers 14, 14a may be composed of the same semiconductor material containing nominally the same atomic concentration of the element that provides charge traps in the semiconductor material. In an embodiment, the charge-trapping layers 14, 14a may be composed of the same semiconductor material and contain different atomic concentrations of the element that provides charge traps in the semiconductor material. In an embodiment, the charge-trapping layers 14, 14a may be composed of single-crystal silicon and containing an atomic concentration of carbon atoms within a range of about 0.1 atomic percent to about three (3) atomic percent.

Additional pairs of the layers 14, 24 may be formed over the layers 14a, 24a in the stacked superlattice structure. In an embodiment, the number of pairs of the layers 14, 24 in the stacked superlattice structure may range from two (2) to ten (10).

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “in direct contact with” another feature if intervening features are absent. A feature may be “indirectly on” or “in indirect contact with” another feature if at least one intervening feature is present.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor substrate; and
a layer stack on the semiconductor substrate, the layer stack including a buffer layer and a first charge-trapping layer, the buffer layer comprised of a III-V compound semiconductor material, and the first charge-trapping layer positioned between the semiconductor substrate and the buffer layer.

2. The structure of claim 1 wherein the first charge-trapping layer is comprised of a single-crystal semiconductor material containing an atomic concentration of an element that provides charge traps in the single-crystal semiconductor material.

3. The structure of claim 1 wherein the first charge-trapping layer is comprised of single-crystal silicon containing an atomic concentration of an element from Group IV of the Periodic Table.

4. The structure of claim 1 wherein the first charge-trapping layer is comprised of single-crystal silicon containing an atomic concentration of carbon.

5. The structure of claim 4 wherein the atomic concentration of carbon in the single-crystal silicon is within a range of about 0.1 atomic percent to about 3 atomic percent.

6. The structure of claim 1 wherein the first charge-trapping layer is comprised of single-crystal silicon and contains an atomic concentration of a non-doping element in the single-crystal silicon.

7. The structure of claim 1 wherein the layer stack further includes a first cap layer positioned between the first charge-trapping layer and the buffer layer.

8. The structure of claim 7 wherein the first cap layer and the first charge-trapping layer are comprised of a single-crystal semiconductor material, the single-crystal semiconductor material of the first charge-trapping layer contains an atomic concentration of carbon, and the first cap layer is free of carbon.

9. The structure of claim 7 wherein the layer stack further includes a second charge-trapping layer, and the first cap layer is positioned between the first charge-trapping layer and the second charge-trapping layer.

10. The structure of claim 9 wherein the layer stack further includes a second cap layer, and the second charge-trapping layer is positioned between the first cap layer and the second cap layer.

11. The structure of claim 9 wherein the first charge-trapping layer and the second charge-trapping layer are comprised of a single-crystal semiconductor material containing an atomic concentration of an element that provides charge traps in the single-crystal semiconductor material.

12. The structure of claim 9 wherein the first charge-trapping layer and the second charge-trapping layer are comprised of single-crystal silicon containing an atomic concentration of an element from Group IV of the Periodic Table.

13. The structure of claim 9 wherein the first charge-trapping layer and the second charge-trapping layer are comprised of single-crystal silicon containing an atomic concentration of carbon.

14. The structure of claim 13 wherein the atomic concentration of carbon in the single-crystal silicon is within a range of about 0.1 atomic percent to about 3 atomic percent.

15. The structure of claim 9 wherein the first charge-trapping layer and the second charge-trapping layer are comprised of single-crystal silicon and contain an atomic concentration of a non-doping element in the single-crystal silicon.

16. The structure of claim 1 further comprising:
a channel layer positioned over the layer stack, the channel layer comprised of a single-crystal III-V compound semiconductor material.

17. The structure of claim 16 further comprising:
a high-electron-mobility transistor having a gate over the channel layer.

18. A method comprising:
forming a charge-trapping layer on a semiconductor substrate; and
forming a buffer layer on the charge-trapping layer,
wherein the buffer layer is comprised of a III-V compound semiconductor material, and the charge-trapping layer is positioned between the semiconductor substrate and the buffer layer.

19. The method of claim 18 wherein forming the charge-trapping layer on the semiconductor substrate comprises:
epitaxially growing the charge-trapping layer on the semiconductor substrate.

20. The method of claim 18 wherein the charge-trapping layer is comprised of single-crystal silicon containing an atomic concentration of carbon, and the atomic concentration of carbon in the single-crystal silicon is within a range of about 0.1 atomic percent to about three (3) atomic percent.
